(19) United States
(12) Patent Application Publication
(10) Pub. No.: US 2016/0211393 A1
(43) Pub. Date: Jul. 21, 2016

(54) Tunnel Diode With Broken-Gap Quantum Well

(71) Applicant: The Government of the United States of America, as Represented by the Secretary of the Navy, Arlington, VA (US)

(72) Inventors: Matthew P. Lumb, Washington, DC (US); Shawn Mack, Alexandria, VA (US); Maria Gonzalez, Washington, DC (US); Kenneth Schmieder, Alexandria, VA (US); Robert J. Walters, Alexandria, VA (US)

(73) Assignee: The Government of the United States of America, as Represented by the Secretary of the Navy, Arlington, VA (US)

(21) Appl. No.: 14/995,357

(22) Filed: Jan. 14, 2016

Related U.S. Application Data
(60) Provisional application No. 62/104,110, filed on Jan. 16, 2015.

(51) Int. Cl. H01L 31/0352; H01L 31/0735

(52) U.S. Cl. CPC H01L 31/035236; H01L 31/0735

(57) ABSTRACT

A broken-gap tunnel junction device comprising a thin quantum well (QW) layer situated at the interface between adjacent highly doped n-type and p-type semiconductor layers, wherein the QW layer has a type-III broken-gap energy band alignment with respect to one or more of the surrounding semiconductor layers such that a conduction band of the QW layer is below the valence band of one or more of the n-type and p-type bulk semiconductor layers.

### CROSS-REFERENCE

This Application is a nonprovisional of and claims the benefit of priority under 35 U.S.C. §119 based on Provisional Application No. 62/104,110 filed on Jan. 16, 2015. The Provisional Application and all references cited herein are hereby incorporated by reference into the present disclosure in their entirety.

### TECHNICAL FIELD

The present invention relates to semiconductor heterostructures, particularly to heterostructures forming a tunnel junction in a semiconductor device.

### BACKGROUND

Multi-junction (MJ) solar cells embody state of the art high efficiency solar cell technology, with theoretical maximum efficiencies of ˜63% for a triple junction cell and ˜86% for a cell having an infinite series of junctions. See Alexis De Vos, “Detailed Balance Limit of the Efficiency of Tandem Solar-Cells,” J. Phys. D: Appl. Phys., vol. 13, pp. 839-846, 1980. MJ solar cells currently hold the highest conversion efficiency recorded, having demonstrated conversion efficiencies >46% under concentrated sunlight. See Martin A. Green, Keith Emery, Yoshihiro Hishikawa, Wilhelm Warta, and Ewan D. Dunlop, “Solar cell efficiency tables (Version 45),” Progress in Photovoltaics: Research and Applications, vol. 23, pp. 1-9, 2015.

A monolithic MJ solar cell consists of semiconductor layers deposited sequentially on top of each other to form two or more series connected subcells. The subcells absorb incident sunlight and convert the light to electricity. In an ideal MJ solar cell, each subcell absorbs the light having an energy greater than the bandgap of that subcell and transmits the remaining light to the cell beneath. For a given number of junctions, the maximum efficiency of the solar cell is achieved when the band-gaps of the respective subcell materials split the incident solar spectrum optimally among the subcells so that the photocurrents of each subcell are well matched and the thermalization loss is minimized.

Tunnel junctions, also known as Esaki diodes, connect the subcells of a monolithic MJ stack in electrical series, and are an important component of MJ solar cells.

For optimal performance in MJ solar cells, it is important that the tunnel junction (TJ) have certain electrical properties. For example, the TJ should have peak tunnel current density high enough to not impede the flow of photocurrent between the subcells, which can reach tens of A/cm² in sun-concentrator applications. F. Dimroth, “High-efficiency solar cells from III-V compound semiconductors,” Phys. Status Solidi C, vol. 3, pp. 373-379, 2006. In addition, the differential resistance of the TJ should be as low as possible to minimize any voltage drop across the diode. Finally, the TJ should be as transparent as possible to light with energy below the band gap of the cell directly above the TJ, both to minimize the filtering of the light to the cell beneath and also to minimize the possibility of photocurrent being produced by the TJ.

Recent calculations by NRL researchers have identified GaSb-based MJ materials as potential candidates for the next generation of record-breaking solar cell efficiency structures. See Matthew P. Lumb, Kenneth J. Schmieder, Maria Gonzalez, Shawn Mack, Michael K. Yakes, Matthew Meitl, Scott Burroughs, Chris Ebert, Mitchell F. Bennett, David V. Forbes, Xing Sheng, John A. Rogers, and Robert J. Walters, “Realizing the Next Generation of CPV Cells Using Transfer Printing,” in CPV-11, Aix les Bains, France, 2015. However, GaSb homojunctions grown by molecular beam epitaxy typically do not make high-performance tunnel junctions because donor concentrations using Te as a dopant saturate at non-degenerate levels, typically at 1−2×10¹⁸ cm⁻³. See S. Subbanna, G. Tuttle, and H. Kroemer, “N-type doping of gallium antimonide and aluminum antimonide grown by molecular beam epitaxy using lead telluride as a tellurium dopant source,” Journal of Electronic Materials, vol. 17, pp. 297-303, 1988. This leads to a wide depletion region, which greatly limits the tunneling current in such devices.

GaSb/InAs heterojunctions make conductive tunnel junctions because of the broken band alignment and degenerate electron concentrations in InAs. See Kristijonas Vizbaras, Marcel Törpe, Shamsul Arafin, and Markus-Christian Amann, “Ultra-low resistive GaSb/InAs tunnel junctions,” Semicond. Sci. Technol. 26, 075021 (2011). However, the InAs layer has a narrow bandgap and can absorb photons passing through GaSb layers.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a tunnel junction device comprising a thin quantum well (QW) layer situated at the interface between adjacent highly doped n-type and p-type semiconductor material layers, wherein the QW layer has a type-III, or “broken-gap,” energy band alignment with respect to one or both of the surrounding semiconductor layers such that the conduction band of the QW layer is below the valence band of one or more of the n-type and p-type bulk semiconductor layers.

In an exemplary embodiment, the device includes an 8 nm-thick n-type InAs QW layer situated at the interface between a 40 nm-thick p-type GaSb layer and a 40 nm-thick n-type GaSb layer.

In other embodiments, materials such as AlₓGa₁₋ₓAs_{1-y}Sb_{y}, AlₓGa₁₋ₓP_{1-y}Sb_{y}, InₓAl₁₋ₓAs_{1-y}Sb_{y}, InₓAl_{y}Ga_{1-x-y}Sb, InₓAl_{y}Ga_{1-x-y}As, and InₓGa₁₋ₓAs_{1-y}Sb_{y} can be used, where the materials may or may not be lattice matched to the substrate.

In some embodiments, the materials used for the p-type and n-type bulk semiconductor layers are the same; in other embodiments, the p- and n-type materials can be different.

In still other embodiments, the materials for the QW, the p-type semiconductor layer and the n-type semiconductor layer can be selected such that the QW exhibits a broken gap band structure with respect to only one of the p-type and n-type layers, while exhibiting a conventional type-I or type-II band-gap structure with respect to the other.

The presence of the broken-gap quantum well (BG-QW) improves the performance of semiconductor devices of which they are a part by facilitating the tunneling of carriers between p- and n-type materials in the TJ. Because the quantum well layer is thin, typically less than 10 nm, the presence of the quantum well has only a small impact on the TJ's transparency, making a BG-QWTJ device in accordance with the present invention especially suitable for use not only in multijunction solar cells but also in other semiconductor devices such as interband cascade lasers or mid-wave and long-wave IR photodetectors.

### BRIEF DESCRIPTION OF THE DRAWINGS

FIGS. 1A and 1B are block diagram plots illustrating aspects of semiconductor band structures relevant to a broken-gap quantum well tunnel junction in accordance with the present invention.

FIGS. 2A-2C are plots further illustrating aspects of semiconductor band structures relevant to a broken-gap quantum well tunnel junction in accordance with the present invention.

FIG. 3 is a contour plot illustrating of the energy difference in electron volts between the valence band (VB) of Al_{y}Ga_{1-y}Sb and the conduction band (CB) of the lattice matched quaternary (GaSb)₁₋ₓ(InAs_{0.91}Sb_{0.09})ₓ at different values of x and y.

FIG. 4 is a block diagram plot showing semiconductor band structures for an exemplary quantum well tunnel junction device having a type-III broken gap band structure at only one heterointerface between the quantum well material and the p-type and n-type bulk semiconductor materials.

FIG. 5 provides current-voltage plots of a conventional GaSb tunnel junction and a broken-gap quantum well tunnel junction in accordance with the present invention.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

Tunnel junctions (TJs) are critical components of multi-junction photovoltaics that must pass high current densities with low resistance and high optical transparency. TJs connect monolithic subcells in electrical series, situated between a wide bandgap upper cell and a narrower bandgap lower cell. Ideally, photons below the bandgap of the upper cell will not be filtered by the TJ and may be converted to electricity by the cell beneath.

Interfaces between III-V alloys in a semiconductor heterostructure exhibit a variety of possible band alignments depending on the composition of the materials involved. This gives rise to a rich array of material configurations which can be used to modify, enhance or tailor the optical and electrical properties of such compound semiconductors and related devices.

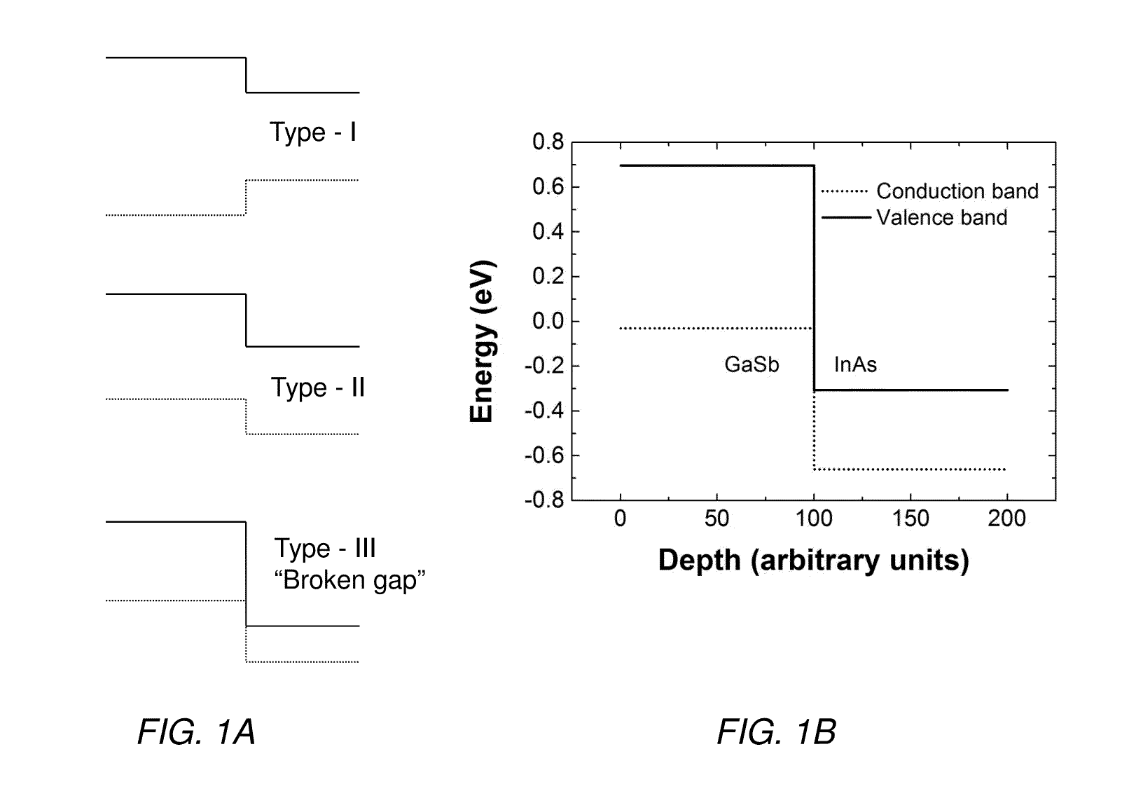

The plots in FIG. 1A illustrate the three types of conduction and valence band alignment in a semiconductor hetero structure.

In a structure having a “Type-I” alignment, the band gap alignment of the second material in the heterostructure lies completely within the band gap of the first material. Typical heterostructures having this kind of alignment include AlₓGa₁₋ₓAs/GaAs used in high-efficiency double-heterostructure light-emitting diodes and laser diodes. See Nick Holonyak, Jr., Robert M. Kolbas, Russell D. Dupuis, and P. Daniel Dapkus, “Quantum-well heterostructure lasers,” IEEE Journal of Quantum Electronics, vol. 16, pp. 170-186, 1980.

In a structure having a “Type-II” alignment, also known as “staggered gap,” the bandgaps of the two materials are staggered, with both the conduction and valence bands of the second material being lower than the conduction and valence bands of the first. This configuration is commonly found in InₓGa₁₋ₓAs/GaAs_{1-y}Sb_{y} quantum well light emitting diodes and laser diodes. See M. Peter, R. Kiefer, F. Fuchs, N. Herres, K. Winkler, K.-H. Bachem, and J. Wagner, “Light-emitting diodes and laser diodes based on a Ga₁₋ₓInₓAs/GaAs_{1-y}Sb_{y} type II superlattice on InP substrate,” Applied Physics Letters, vol. 74, pp. 1951-1953, 1999.

In a structure having “type-III,” or “broken gap,” alignment, the energy level of the conduction band of one material resides below the valence band of the other. This configuration, sometimes also referred to as “type-II broken gap,” has been successfully employed in mid-wave and long-wave infrared photodetectors and lasers, using, for example, InAs/GaSb superlattices. The broken gap alignment is further illustrated in the plot shown in FIG. 1B, which, using GaSb and InAs as an example, shows the energy level of the InAs conduction band as being lower than the energy level of the GaSb valence band. This type of band alignment allows efficient tunneling between the valence band of GaSb and the conduction band of InAs to take place.

The present invention utilizes combinations of materials exhibiting this broken gap band structure to provide a new, high-performance TJ concept designed to connect a wide bandgap solar cell to a narrow bandgap solar cell with low electrical resistance and low optical loss. A TJ in accordance with the present invention overcomes the deficiencies in bulk homojunctions and heterojunctions discussed above and provides significantly better performance.

Recent work at the Naval Research Laboratory (NRL) indicated that AlₓGa₁₋ₓAs_{1-y}Sb_{y} and InₓGa₁₋ₓAs_{1-y}Sb_{y} materials are potential candidates to make high transparency, high performance TJs. See Lumb et al., supra. These quaternaries can be grown with a wide range of bandgaps lattice-matched to GaSb. However, high doping is a critical requirement of high performance TJs, and initial experiments at NRL to make GaSb p++/n++ TJs exhibited poor performance due to the limited level of active n-type dopant that can be achieved. For example, GaSb can be Te-doped only up to concentrations in the low −10¹⁸ cm⁻³ range, which proved insufficient to realize high performance TJs.

Other authors have demonstrated that it is possible to make tunneling heterostructures which exploit the broken gap alignment between GaSb and InAs in devices that were p++ GaSb/n++ InAs heterostructures, where the n-type GaSb is replaced by InAs. See Vizbaras et al., supra. This type of band alignment allows efficient tunneling from the valence band of GaSb into the conduction band of InAs. However, the drawback of this approach is that InAs is a narrow bandgap semiconductor and introduces significant absorption losses for light transmitted to the cell beneath the TJ.

The present invention overcomes the drawbacks of such tunnel junctions employing p/n GaSb homojunctions and p-type GaSb/n-type InAs heterojunctions by adding a single thin QW layer at the interface between highly doped p-type and n-type layers of the tunnel junction. The composition of the materials is such that the QW forms a type-III, or “broken-gap,” alignment with one or more of the surrounding semiconductor layers, and thus such a device is known as a “broken-gap quantum well tunnel junction” or “BG-QWTJ”. The presence of the broken-gap quantum well (BG-QW) improves the performance of semiconductor devices of which they are a part by facilitating the tunneling of carriers between p- and n-type materials in the TJ. Because the QW is thin, typically less than 10 nm, the presence of the QW has only a small impact on the structure's transparency.

Thus, in accordance with the present invention, by placing a single narrow InAs quantum well at the interface of a GaSb homojunction a broken-gap quantum well tunnel junction (BG-QWTJ) can be formed, where the BG-QWTJ can facilitate tunneling of carriers by significantly reducing the height and width of the energy barrier that the carriers must traverse. In addition, because the single QW layer is weakly absorbing compared to the thicker, bulk InAs layer in a conventional TJ configuration, the transparency of the TJ is not compromised by the addition of the BG-QW layer, making a BG-QWTJ device in accordance with the present invention suitable for use not only in multijunction solar cells but also in other semiconductor devices such as interband cascade lasers or mid-wave and long-wave IR photodetectors.

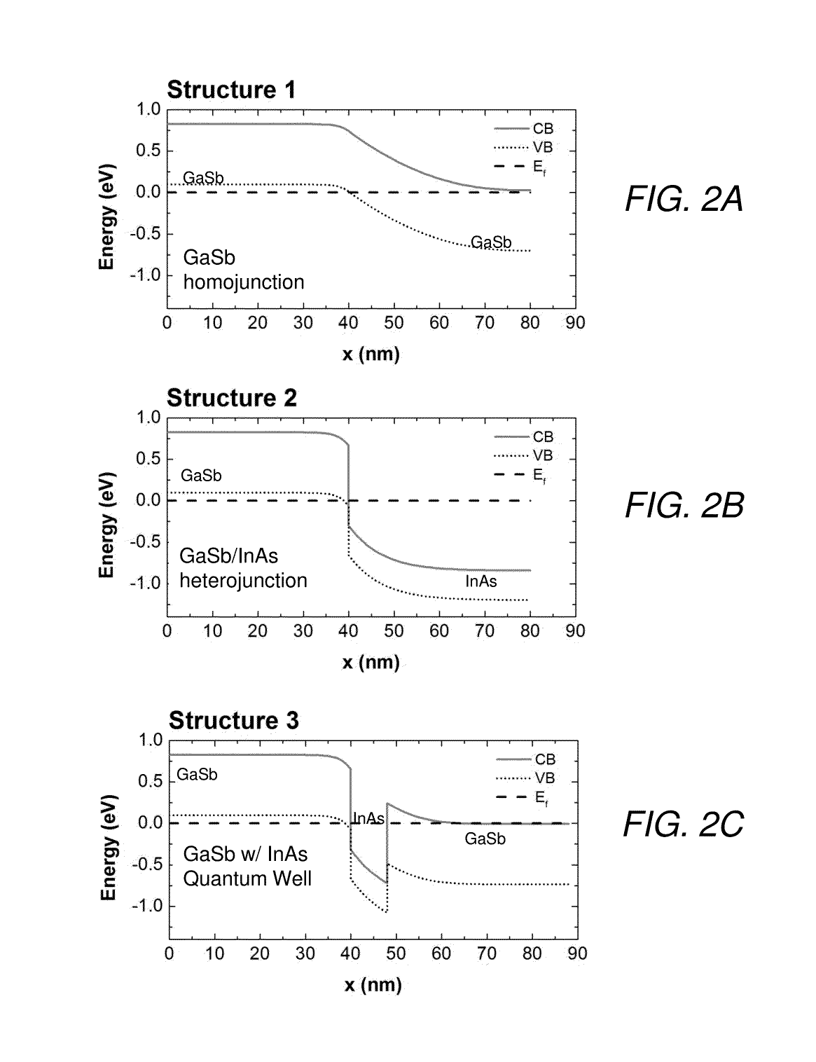

The advantages of the BG-QWTJ in accordance with the present invention can be seen from the plots in FIGS. 2A-2C, which depict the equilibrium band diagrams of three exemplary modeled tunnel junction structures, denoted as Structures 1, 2, and 3, where Structure 1 is a conventional p/n GaSb/GaSb tunnel junction, Structure 2 is a conventional p/n GaSb/InAs heterojunction, and Structure 3 is a broken-gap quantum well tunnel junction (BG-QWTJ) in accordance with the present invention. The composition and structure of Structures 1, 2, and 3 are summarized in Table 1 below.

TABLE 1

| | Material | Thickness (nm) | Dopant | Conc. (cm⁻³) |
|---|---|---|---|---|
| Structure 1 | | | | |
| p-type layer | GaSb | 40 | Si | 1.2 × 10¹⁹ |
| n-type layer | GaSb | 40 | Te | 2 × 10¹⁸ |
| Structure 2 | | | | |
| p-type layer | GaSb | 40 | Si | 1.2 × 10¹⁹ |
| n-type layer | InAs | 40 | Si | 1.2 × 10¹⁹ |
| Structure 3 | | | | |
| p-type layer | GaSb | 40 | Si | 1.2 × 10¹⁹ |
| n-type QW | InAs | 8 | Si | 1.2 × 10¹⁹ |
| n-type layer | GaSb | 40 | Te | 2 × 10¹⁸ |

The band structure of these modeled Structures 1, 2, and 3 were calculated using the NRL MULTIBANDS® modeling software described in Matthew P. Lumb, Igor Vurgaftman, Chaffra A. Affouda, Jerry R. Meyer, Edward H. Aifer and Robert J. Walters, “Quantum wells and superlattices for III-V photovoltaics and photodetectors,” in Proceedings of SPIE, Next Generation (Nano) Photonic and Cell Technologies for Solar Energy Conversion III, San Diego, 2012, p. 84710A.

The band diagram of the exemplary conventional p/n GaSb/GaSb tunnel junction having Structure 1 is shown in FIG. 2A. In such a conventional tunnel junction, elastic band-to-band tunneling occurs through the forbidden gap of the GaSb material between the conduction and valence band of the materials on either side of the junction. Inelastic tunneling may also occur through defect states within the forbidden gap. In both cases, the tunneling probability is increased by highly doping the p-type and n-type layers, thereby reducing the overall potential barrier for carriers tunneling across the forbidden gap. Photons with energies less than the bandgap of GaSb (0.72 eV) are not absorbed by this architecture, therefore this particular TJ is suitable for use in series connecting a GaSb solar cell to a narrower bandgap solar cell (<0.72 eV). However, the electrical performance of this device is limited by the ability to highly n-dope GaSb, which dramatically reduces the tunneling probability.

The band structure of the exemplary conventional p/n GaSb/InAs heterostructure tunnel diode having Structure 2 is shown in FIG. 2B. In this device, the conduction band of the n-type InAs layer is lower than the valence band of the p-type GaSb layer. As a result, this device has a much more efficient tunneling mechanism due to the broken band gap alignment between the p- and n-type layers, which removes the potential barrier for carriers tunneling between the conduction band and valence band at the heterointerface. Such devices have very low electrical resistance at the junction and high electrical performance. However, they are not ideal for use in MJ solar cells because the InAs bandgap is narrower than that of GaSb, and consequently, the InAs will absorb light having energies below the bandgap of GaSb, increasing transmission losses to the solar cell beneath.

The band structure of Structure 3, an exemplary BG-QWTJ in accordance with the present invention, is shown in FIG. 2C. As noted above, this exemplary structure includes an 8 nm-thick n-type InAs QW layer situated at the interface between a 40 nm-thick p-type GaSb layer and a 40 nm-thick n-type GaSb layer. As can be seen in FIG. 2C, the n-type InAs QW layer introduces “broken gap” conduction band states that are below the valence band of both the p-type and n-type GaSb layers, and therefore provides a high probability tunnel path between the conduction band and valence band. Majority carriers either side of the QW see only small thermionic barriers due to the band bending close to the junction and therefore circumvent the large tunnel barrier present in Structure 1. Furthermore, the QW absorbs the light very weakly due to the weak absorption from the single, thin QW and the additional reduction in oscillator strength for band to band transitions due to the spatial separation of the electron and hole wavefunctions around the QW arising from the broken-gap band alignment.

Thus, the present invention provides a BG-QWTJ device comprising a p-type bulk semiconductor layer adjacent to an n-type bulk semiconductor, with a thin (typically <10 nm) quantum well situated between the n- and p-type layers.

Although a GaSb/InAs structure has been described, a BG-QWTJ device in accordance with the present invention can take many forms.

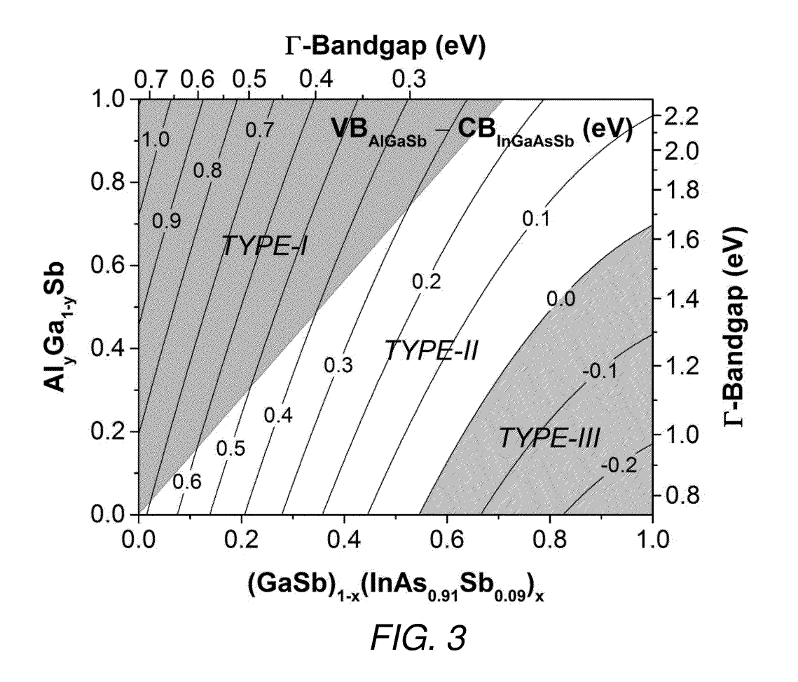

For example, there are wide ranges of III-V alloy compositions which exhibit type-III band alignments, for both lattice-matched and strained materials. FIG. 3 is a contour plot illustrating aspects of the room-temperature band alignment of the quaternary alloy InGaAsSb and the ternary alloy AlGaSb for InGaAsSb material that is lattice-matched to GaSb. The contours on the figure show the energy difference in electron volts between the valence band (VB) of Al_{y}Ga_{1-y}Sb and the conduction band (CB) of the lattice matched quaternary (GaSb)₁₋ₓ(InAs_{0.91}Sb_{0.09})ₓ at various values of x and y. The three shaded regions show the types of band alignment, i.e., type-I, type-II, or type-III alignment, for a tunnel junction comprising materials having various compositions, where a negative value at a contour implies that the band alignment is type-III in nature.

As can be seen from FIG. 3, such a type-III alignment exists over a wide composition range of Al_{y}Ga_{1-y}Sb and (GaSb)₁₋ₓ(InAs_{0.91}Sb_{0.09})ₓ. Similar curves can be constructed for similar alloys with arbitrary strain. This figure shows that BG-QWTJs in accordance with the present invention can be constructed with bulk AlGaSb barrier layers over a wide range of compositions and still maintain a type-III band alignment with an InGaAsSb quantum well. This allows TJs with varying transparency to be realized by changing the AlGaSb bandgap, with the TJs still retaining a high tunnel probability through the type-III quantum well.

Thus, although the BG-QWTJ device in accordance with the present invention is described above in the context of a heterostructure comprising GaSb-based p- and n-type bulk semiconductor layers and an InAs-based quantum well layer, BG-QWTJ devices in accordance with the present invention can also include any suitable heterostructure system exhibiting a broken-gap band alignment. Materials such as AlₓGa₁₋ₓAs_{1-y}Sb_{y}, AlₓGa₁₋ₓP_{1-y}Sb_{y}, InₓAl₁₋ₓAs_{1-y}Sb_{y}, InₓAl_{y}Ga_{1-x-y}Sb, InₓAl_{y}Ga_{1-x-y}As and InₓGa₁₋ₓAs_{1-y}Sb_{y} all exhibit a broken gap band alignment to another alloy from the same set over a part of their composition range and so can be used to form a BG-QWTJ device in accordance with the present invention. For example, using only binary and ternary materials lattice-matched to an InAs substrate, an InAs QW, and p- and n-type GaAs_{0.08}Sb_{0.92} layers or p- and n-type GaP_{0.06}Sb_{0.94} layers may be used to obtain a BG-QW system.

However, as noted above, suitable compositions are not limited to lattice-matched alloys, and consequently, any broken-gap combination of AlGaAsSb, AlGaPSb, InAlAsSb, InAlGaSb, InAlGaAs, and InGaAsSb may be used to form a BG-QWTJ device in accordance with the present invention.

In addition, there also is no requirement that the p-type and n-type semiconductor material layers be identical, so that in some embodiments, they may be formed from different semiconductor alloys instead. For example, in some embodiments, the p-type semiconductor layer can be GaP_{0.06}Sb_{0.94} while the n-type semiconductor layer can be GaAs_{0.08}Sb_{0.92}, with an n-type InAs QW situated therebetween, the InAs QW having a broken gap band alignment with both the p- and n-type material layers.

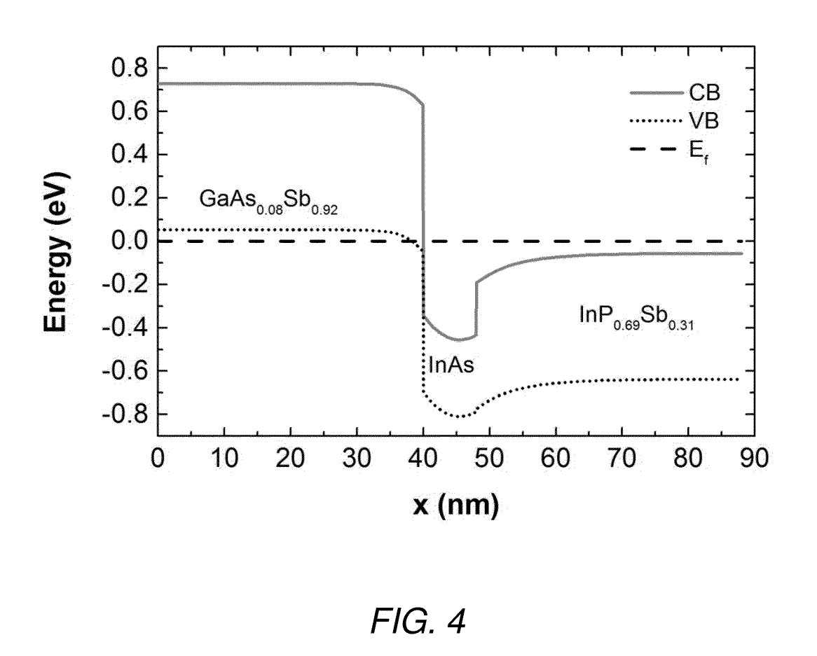

Moreover, there is also no requirement that both hetero-interfaces of the QW have a broken gap band alignment with respect to their surrounding materials. Thus, a BG-QWTJ device in accordance with the present invention can be formed using, for example, a p-type GaAs_{0.08}Sb_{0.92} layer, an n-type InAs QW, and an n-type InP_{0.69}Sb_{0.31} layer, with the device having the device has the band structure shown in FIG. 4, where the GaAs_{0.08}Sb_{0.92} n-type material and the InAs QW have a broken gap band alignment while the band alignment between the InP_{0.69}Sb_{0.31} p-type material and the InAs QW is a type-II staggered gap.

### EXAMPLE

To demonstrate the effectiveness of the BG-QWTJ architecture in accordance with the present invention, multijunction solar cells having Structure 1 and Structure 3 tunnel junctions, respectively, were deposited by molecular beam epitaxy and processed into circular devices with a radius of 0.5 mm. Each device was grown on a p-type GaSb wafer and contained a thin (10 nm) n++ InAs contact layer to achieve an Ohmic contact at the front surface.

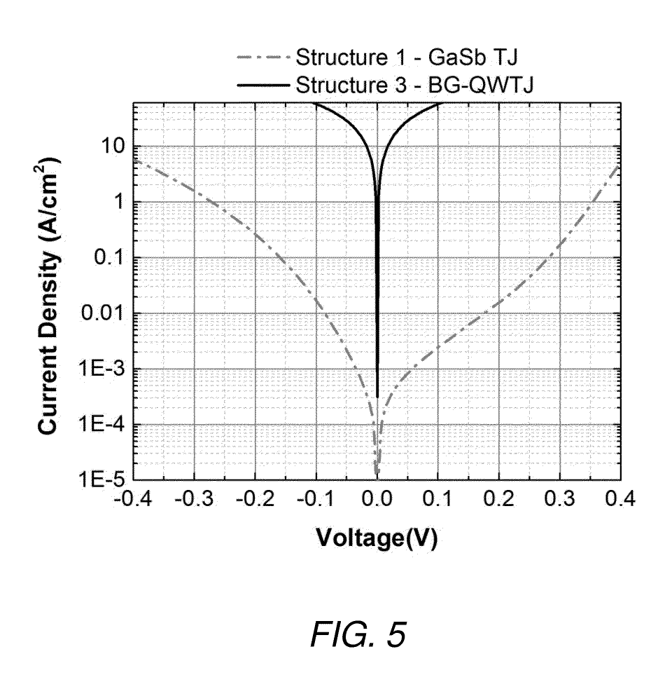

The current-voltage (IV) characteristics of the devices are shown by the plots in FIG. 5, which show the measured current-voltage characteristics for the Structure 3 BG-QWTJ device in accordance with the present invention compared to the Structure 1 bulk GaSb device. As can be readily seen from the FIGURE, Structure 1 shows rectifying behavior, with no evidence of tunneling behavior in forward bias. In contrast, Structure 3 has a linear IV curve with a low differential resistance of 1.7×10⁻³ Ωcm², suitable for use in a high-performance multi-junction solar cell. The linear IV curve is maintained to equivalent current densities of many thousands of suns concentration, where the 1 sun photocurrent of 7 mA/cm² is estimated from simulations of a GaSb based solar cell mechanically stacked with a GaAs-based triple junction solar cell.

Advantages and New Features:

The BG-QWTJ structure in accordance with the present invention has been shown to dramatically improve the device performance relative to a baseline bulk GaSb TJ. This gives the potential for MJ solar cells with reduced resistive losses and therefore higher efficiencies, particularly at high solar concentration values where photocurrents can be very large.

The key feature of this invention is the inclusion of a single thin QW layer having a type-III broken-gap alignment at the interface between the p- and n-type regions of the tunnel junction; the broken gap alignment of the QW alleviates the requirement for high n-type doping in the bulk layers of the TJ, but the weak absorption of the single QW has only a minor impact on the transparency of the device.

Although TJs incorporating QWs to improve the tunnel probability and maintain high transparency have been demonstrated before with lattice-matched QW pairs, see Matthew P. Lumb, Michael K. Yakes, María González, Igor Vurgaftman, Christopher G. Bailey, Raymond Hoheisel, and Robert J. Walters, “Double quantum-well tunnel junctions with high peak tunnel currents and low absorption for InP multi-junction solar cells,” Appl. Phys. Lett., vol. 100, p. 213907, 2012; strain-balanced QW pairs, see Michael K. Yakes, Matthew P. Lumb, Christopher G. Bailey, Maria Gonzalez, and Robert J. Walters, “Strain balanced double quantum well tunnel junctions,” in Photovoltaic Specialists Conference (PVSC), 2013 IEEE 39th, 2013, pp. 2147-2150; and a single interface Q W, see Joshua P. Samberg, C. Zachary Carlin, Geoff K. Bradshaw, Peter C. Colter, Jeffrey L. Harmon, J. B. Allen, John R. Hauser, and S. M. Bedair, “Effect of GaAs interfacial layer on the performance of high bandgap tunnel junctions for multijunction solar cells,” Appl. Phys. Lett., 103, 103503 (2013), all of these previous devices have used type-I quantum wells, whereas the key new feature of this invention is the creation of a QW having type-III band alignment, which has an extremely high tunnel probability and represents a significant improvement over the prior art devices.

Although particular embodiments, aspects, and features have been described and illustrated in the present disclosure, one skilled in the art would readily appreciate that the invention described herein is not limited to only those embodiments, aspects, and features but also contemplates any and all modifications within the spirit and scope of the underlying invention described and claimed herein, and such combinations and embodiments are within the scope of the present disclosure.

What is claimed is:

1. A broken-gap quantum well tunnel junction device, comprising:
a substrate;
a single thin quantum well (QW) material layer, a p-type semiconductor material layer, and an n-type semiconductor material layer on the substrate, the QW material layer being situated between the p-type semiconductor material layer and the n-type semiconductor material layer to form a quantum well tunnel junction (QWTJ);
wherein a conduction band of the QW material is lower than a valence band of at least one of the p-type semiconductor material and the n-type semiconductor material to form a broken-gap band configuration at an interface between the QW material layer and the at least one of the p-type and the n-type semiconductor material layers.

2. The broken-gap quantum well tunnel junction device according to claim 1, wherein a thickness of the QW material layer is configured to maximize a transparency of the tunnel junction.

3. The broken-gap quantum well tunnel junction device according to claim 1, wherein the QW material layer has a thickness of less than about 10 nm.

4. The broken-gap quantum well tunnel junction device according to claim 1, wherein the QW material layer is an InGaAsSb alloy.

5. The broken-gap quantum well tunnel junction device according to claim 1, wherein each of the p-type and n-type semiconductor material layers is an AlGaSb alloy.

6. The broken-gap quantum well tunnel junction device according to claim 1, wherein each of the QW material layer, the p-type semiconductor material layer, and the n-type semiconductor material layer is one of AlGaAsSb, AlGaPSb, InAlAsSb, InAlGaSb, InAlGaAs and InGaAsSb.

7. The broken-gap quantum well tunnel junction device according to claim 1, wherein each of the QW material layer, the p-type semiconductor material layer, and the n-type semiconductor material layer is one of AlₓGa₁₋ₓAs_{1-y}Sb_{y}, AlₓGa₁₋ₓP_{1-y}Sb_{y}, InₓAl₁₋ₓAs_{1-y}Sb_{y}, InₓAl_{1-y}Ga_{1-x-y}Sb, InₓAl_{y}Ga_{1-x-y}As and InₓGa₁₋ₓAs_{1-y}Sb_{y}, at least one of the QW material layer, the p-type semiconductor material layer, and the n-type semiconductor material layer being lattice-matched to the substrate.

8. The broken-gap quantum well tunnel junction device according to claim 1, wherein the substrate is an InAs substrate, and therein at least one of the QW material layer is InAs, and the p-type semiconductor material layer and the n-type semiconductor material layer is lattice-matched to the InAs substrate.

9. The broken-gap quantum well tunnel junction device according to claim 8, wherein at least one of the p-type and n-type semiconductor material layers is GaAs_{0.08}Sb_{0.92}.

10. The broken-gap quantum well tunnel junction device according to claim 8, wherein at least one of the p-type and n-type semiconductor material layers is GaP_{0.06}Sb_{0.94}.

11. The broken-gap quantum well tunnel junction device according to claim 1, comprising a 40 nm-thick p-type GaSb layer, a 40 nm-thick n-type GaSb layer, and an 8 nm-thick InAs QW material layer situated between the p- and n-type GaSb layers.

12. The broken-gap quantum well tunnel junction device according to claim 1, wherein the p- and n-type material layers are the same.

13. The broken-gap quantum well tunnel junction device according to claim 1, wherein the p- and n-type material layers are different, the QW layer having a broken-gap band alignment with both of the p- and n-type material layers.

14. The broken-gap quantum well tunnel junction device according to claim 1, wherein the p- and n-type material layers are different, the QW layer having a broken-gap band alignment with at least one of the p- and n-type material layers.

15. The broken-gap quantum well tunnel junction device according to claim 1, wherein the p- and n-type material layers are different, the QW layer having a broken-gap band alignment with one of the p- and n-type material layers and having a type-I band alignment with the other of the p- and n-type material layers.

16. The broken-gap quantum well tunnel junction device according to claim 1, wherein the p- and n-type material layers are different, the QW layer having a broken-gap band alignment with one of the p- and n-type material layers and having a type-II band alignment with the other of the p- and n-type material layers.

17. The broken-gap quantum well tunnel junction device according to claim 1, wherein the p-type layer is GaP_{0.06}Sb_{0.94} and the n-type layer is GaAs_{0.08}Sb_{0.92}.

18. The broken-gap quantum well tunnel junction device according to claim 1, comprising an GaAs_{0.08}Sb_{0.92} p-type layer, an InP_{0.69}Sb_{0.31} n-type layer, and an n-type InAs QW situated between the p- and n-type layers; wherein the InAs QW has a broken gap band alignment with the n-type GaAs_{0.08}Sb_{0.92} and a type-II staggered gap band alignment with the p-type InP_{0.69}Sb_{0.31}.
